(19) United States
(12) Patent Application Publication
(10) Pub. No.: US 2025/0081641 A1
(43) Pub. Date: Mar. 6, 2025

(54) SCHOTTKY-BARRIER PHOTODETECTOR WITH GERMANIUM

(71) Applicant: SAMSUNG ELECTRONICS CO., LTD., Suwon-si (KR)

(72) Inventor: Chanwook BAIK, Suwon-si (KR)

(73) Assignee: SAMSUNG ELECTRONICS CO., LTD., Suwon-si (KR)

(21) Appl. No.: 18/659,417

(22) Filed: May 9, 2024

(30) Foreign Application Priority Data
Aug. 31, 2023 (KR) 10-2023-0115602

(51) Int. Cl. H01L 27/146; H01L 31/0224; H01L 31/028; H01L 31/0312; H01L 31/108

(52) U.S. Cl. CPC H10F 39/8033; H10F 39/184; H10F 30/227; H10F 77/122; H10F 77/1226; H10F 77/244

(57) ABSTRACT

A photodetector includes a first semiconductor layer including germanium, a conductive layer that, in conjunction with the first semiconductor layer, forms a Schottky junction structure, and a tunneling barrier layer positioned between the first semiconductor layer and the conductive layer and configured to prevent dark current between the first semiconductor layer and the conductive layer.

### CROSS-REFERENCE TO RELATED APPLICATION

This application is based on and claims priority under 35 U.S.C. § 119 to Korean Patent Application No. 10-2023-0115602, filed on Aug. 31, 2023, in the Korean Intellectual Property Office, the disclosure of which is incorporated by reference herein in its entirety.

### BACKGROUND

### 1. Field

The disclosure relates to a Schottky-barrier photodetector.

### 2. Description of the Related Art

Existing photodetectors have generally used a silicon-based P-N junction structure that operates mainly in the visible light band. This structure has been used in various kinds of complementary metal oxide semiconductor (CMOS) image sensors, particularly, due to the high light absorption rate of silicon in the visible light band, the excellent linearity of photocurrent, high quantum efficiency (80%), low noise, and the low price of silicon. Meanwhile, photodiodes utilizing the silicon-based P-N junction may not absorb low energy photons such as photons having lower energy than the bandgap energy (1.12 eV) of silicon. Accordingly, silicon photodiodes or silicon CMOS image sensors including silicon photodiodes have been used in cameras for visible light (400 nm to 700 nm).

The light absorption of silicon does not occur well or is limited in the near infrared (NIR) or short-wavelength infrared (SWIR) band due to its longer wavelengths compared to visible light.

### SUMMARY

There is provided a photodetector capable of detecting light of a wide wavelength band.

There is provided a photodetector capable of reducing or preventing dark current.

Additional aspects will be set forth in part in the description which follows and, in part, will be apparent from the description, or may be learned by practice of the presented embodiments of the disclosure.

A photodetector according to an aspect of the disclosure photodetector may include a first semiconductor layer, a conductive layer that, together with the first semiconductor layer, forms a Schottky junction structure, and a tunneling barrier layer positioned between the first semiconductor layer and the conductive layer and configured to prevent dark current between the first semiconductor layer and the conductive layer, wherein the first semiconductor layer may include germanium (Ge).

According to an embodiment, the first semiconductor layer may include intrinsic Ge, amorphous-Ge, epitaxially grown Ge, or GeₓSn₁₋ₓ(0<x<1).

According to an embodiment, the photodetector may further include a semiconductor substrate. The first semiconductor layer may be formed on the semiconductor substrate.

According to an embodiment, the photodetector may further include a semiconductor substrate doped with one of a p type and an n type, and a second semiconductor layer formed on the semiconductor substrate and doped with another one of the p type and the n type. The first semiconductor layer may be formed on the second semiconductor layer. The first semiconductor layer may be doped with one of a p-type and an n-type.

According to an embodiment, the photodetector may further include: a semiconductor substrate doped with one of a p type and an n type, and a doping region formed in the semiconductor substrate and doped with another one of the p type and the n type. The first semiconductor layer may be formed on the doping region.

According to an embodiment, the conductive layer may include a first conductive layer that, together with the semiconductor layer, forms a Schottky junction structure.

According to an embodiment, the conductive layer may include a second conductive layer positioned on the first conductive layer and being transparent.

According to an embodiment, the first conductive layer may include a metal, an alloy, a metal oxide, a metal nitride, or a silicide, and the second conductive layer may include indium tin oxide (ITO), indium tungsten oxide (IWO), indium zinc oxide (IZO), gallium doped zinc oxide (GZO), gallium indium zinc oxide (GIZO), or aluminum zinc oxide (AZO).

According to an embodiment, a work function of the first conductive layer may be set such that a Schottky barrier height of the Schottky junction structure has a lower value than that of a junction structure of the second conductive layer and the semiconductor layer.

According to an embodiment, the tunneling barrier layer may increase a thickness of a Schottky barrier formed between the conductive layer and the first semiconductor layer.

According to an embodiment, a difference between a conduction band energy level of the tunneling barrier layer and electron affinity of the first semiconductor layer may be 0.5 eV or less.

According to an embodiment, bandgap energy of the tunneling barrier layer may be greater than bandgap energy of the first semiconductor layer.

According to an embodiment, bandgap energy of the tunneling barrier layer may be 2 eV or more.

According to an embodiment, a thickness of the tunneling barrier layer may be 30 nm or less.

According to an embodiment, the tunneling barrier layer may include a metal oxide semiconductor.

According to an embodiment, the metal oxide semiconductor may include titanium dioxide (TiO₂), tin dioxide (SnO₂), zinc oxide (ZnO), tungsten trioxide (WO₃), niobium pentoxide (Nb₂O₅), barium tin trioxide (BaSnO₃), dizinc tin tetroxide (Zn₂SnO₄), strontium titanium trioxide (SrTiO₃), barium titanium trioxide (BaTiO₃), zinc tritanate (Zn₂Ti₃O₈), silica (SiO₂), alumina (Al₂O₃), hafnia (HfO₂), magnesium oxide (MgO), molybdenum trioxide (MoO₃), diiron trioxide (Fe₂O₃), tantalum pentoxide (Ta₂O₅), tantalum oxynitride (TaON), or diindium trioxide (In₂O₃).

According to an embodiment, the metal oxide semiconductor may include titanium oxide TiO₂, TiO₂₋ₓ (0<x<1), TiO, Ti₂O, Ti₃O, Ti₂O₃, or TiₙO₂ₙ₋₁, wherein n is an integer of 3 to 9.

According to an embodiment, the tunneling barrier layer may include a metal oxide and a silicon oxide.

An image sensor according to an aspect of the disclosure may include a sensor array including a plurality of photosensing elements, wherein each of the plurality of photosensing elements includes a photodetector, and a processor configured to read a photoelectric signal generated from each of the plurality of photosensing elements. The photodetector may include a first semiconductor layer, a conductive layer that, together with the first semiconductor layer, forms a Schottky junction structure, and a tunneling barrier layer positioned between the first semiconductor layer and the conductive layer and configured to prevent dark current between the first semiconductor layer and the conductive layer. The first semiconductor layer may include germanium (Ge).

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic configuration view of a photodetector according to an embodiment;

FIG. 2 is a schematic configuration view of a photodetector according to an embodiment;

FIG. 3 is a schematic configuration view of an implementation example of the photodetector according to an embodiment shown in FIG. 1;

FIG. 4 is a schematic configuration view of an implementation example of the photodetector according to an embodiment shown in FIG. 1;

FIG. 5 is an energy band diagram of the implementation examples of the photodetector shown in FIGS. 3 and 4 while no bias voltage is applied;

FIG. 6 is an energy band diagram of the implementation examples of the photodetector shown in FIGS. 3 and 4 while a reverse bias voltage is applied;

FIG. 7 is a schematic configuration view of an implementation example of the photodetector according to an embodiment shown in FIG. 1;

FIG. 8 is a schematic configuration view of an implementation example of the photodetector according to an embodiment shown in FIG. 1;

FIG. 9 is an energy band diagram of the implementation examples of the photodetector shown in FIGS. 7 and 8 while no bias voltage is applied;

FIG. 10 is an energy band diagram of the implementation examples of the photodetector shown in FIGS. 7 and 8 while a reverse bias voltage is applied;

FIG. 11 is a schematic configuration view of an implementation example of the photodetector according to an embodiment shown in FIG. 2;

FIG. 12 is a schematic configuration view of an implementation example of the photodetector according to an embodiment shown in FIG. 2;

FIG. 13 is an energy band diagram of the implementation examples of the photodetector shown in FIGS. 11 and 12 while no bias voltage is applied;

FIG. 14 is an energy band diagram of the implementation examples of the photodetector shown in FIGS. 11 and 12 while a reverse bias voltage is applied;

FIG. 15 is a schematic configuration view of an implementation example of the photodetector according to an embodiment shown in FIG. 2;

FIG. 16 is a schematic configuration view of an implementation example of the photodetector according to an embodiment shown in FIG. 2;

FIG. 17 is an energy band diagram of the implementation examples of the photodetector shown in FIGS. 15 and 16 while no bias voltage is applied;

FIG. 18 is an energy band diagram of the implementation examples of the photodetector shown in FIGS. 15 and 16 while a reverse bias voltage is applied;

FIG. 19 is a cross-sectional view showing a schematic structure of an image sensor according to an embodiment; and

FIG. 20 is a block diagram showing a circuit configuration of the image sensor of FIG. 19.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments will be described in detail with reference to the accompanying drawings. The embodiments which will be described below are only examples, and various modifications may be made from the embodiments. In the drawings, like reference numerals indicate like components, and components shown in the drawings may be exaggerated in size for clarity and convenience of description.

In the following description, the terms “above” or “on” may include the meaning of above/on in a non-contact state, as well as immediately above/on in a contact state.

Although the terms “first”, “second”, etc. may be used herein to describe various components, these terms are only used to distinguish one component from another. These terms do not intend to limit the components to different materials or structures.

It is to be understood that the singular forms “a,” “an,” and “the” include plural referents unless the context clearly dictates otherwise. Also, it will be understood that when a certain portion “includes” a certain component, the portion does not exclude another component but can further include another component, unless the context clearly dictates otherwise.

As used herein, the terms “portion”, “module”, etc. refers to a unit that processes at least one function or operation, and may be implemented as hardware or software or as a combination of hardware and software.

The term “said” and the similar terms may indicate both single and plural.

If the order of operations constituting a method is not definitely specified, the operations may be performed in appropriate order. All the exemplary terms (for example, etc.) used in the disclosure are to merely describe the technical concept in detail and not intended to limit the scope and spirit of the disclosure unless defined by the following claims.

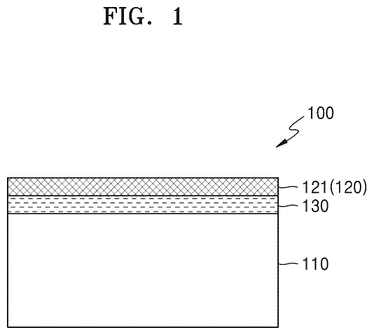

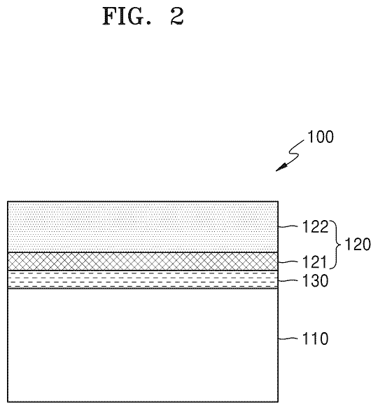

FIGS. 1 and 2 are schematic configuration views of a photodetector 100 according to an embodiment. Referring to FIGS. 1 and 2, the photodetector 100 may include a first semiconductor layer 110, a conductive layer 120 positioned above the first semiconductor layer 110, and a tunneling barrier layer 130 positioned between the first semiconductor layer 110 and the conductive layer 120. A Schottky junction structure may be formed between the conductive layer 120 and the first semiconductor layer 110.

The first semiconductor layer 110 may include germanium (Ge). For example, the first semiconductor layer 110 may include intrinsic-Ge (i-Ge), amorphous Ge, epitaxially grown Ge, or GeₓSn₁₋ₓ (0<x<1). The first semiconductor layer 110 may be doped with one of a p-type and an n-type. For example, a doping concentration of p-Ge may range from 10¹³/cm³ to 10¹⁸/cm³, and a p-type dopant may be boron (B), aluminum (Al), gallium (Ga), indium (In), or tellurium (Te). For example, a doping concentration of n-Ge may range from 10¹³/cm³ to 10¹⁸/cm³, and an n-type dopant may be phosphorus (P), arsenic (As), or antimony (Sb).

A silicon photodiode having an existing P-N junction of silicon may not absorb photons having lower energy than bandgap energy of silicon. Silicon photodiodes or silicon complementary metal oxide semiconductor (CMOS) image sensors as applications of silicon photodiodes are used in cameras for visible light because of having high quantum efficiency in a visible light band (wavelengths of 400 nm to 700 nm). However, because silicon shows low light absorption in a near infrared (NIR) band (wavelengths of 800 nm to 1600 nm), existing silicon photodiodes may be difficult to be used as NIR sensors. Ge absorbs light, for example, in a wavelength band of 800 nm to 1700 nm because of having lower bandgap energy than silicon, and accordingly, Ge photodiodes may be used as NIR sensors or short wavelength infrared (SWIR) sensors.

Therefore, the photodetector 100 according to an embodiment may be configured such that light absorption occurs mainly in the first semiconductor layer 110 including Ge, thereby absorbing infrared light (wavelengths of 800 nm to 1700 nm) of the NIR or SWIR band with high light efficiency. Also, in the photodetector 100, by causing the conductive layer 120 to be in contact with the first semiconductor layer 110 including Ge, a Schottky junction photodiode may be formed instead of a P-N junction layer. By appropriately selecting work functions and energy levels of the first semiconductor layer 110 and the conductive layer 120, photocurrent may be generated in a wide wavelength band of 800 nm to 1700 nm with high quantum efficiency. According to energy of light entering the photodetector 100 being greater than the bandgap energy of Ge, photocurrent may be generated with high efficiency by interband transition in the first semiconductor layer 110. Meanwhile, according to energy of light entering the photodetector 100 being greater than a Schottky barrier height, hot carriers may be generated by an internal photoemission effect in the conductive layer 120, and thus, photocurrent may flow. Because photocurrent is generated by the two effects, high quantum efficiency may be implemented. Also, the photodetector 100 having the Schottky junction may be driven even at a lower voltage than the silicon P-N junction structure while a reverse voltage is applied, and may switch a forward bias voltage to a reverse bias voltage and vice versa at high speed, thereby achieving fast switching. Also, the photodetector 100 having the Schottky junction may be manufactured by a simpler manufacturing process than the P-N junction structure, thereby reducing mass production cost.

The conductive layer 120 may form a Schottky junction together with the first semiconductor layer 110. According to an embodiment, the conductive layer 120 may have a single-layer structure as shown in FIG. 1. For example, the conductive layer 120 may include a first conductive layer 121. The first conductive layer 121 may form a Schottky junction together with the first semiconductor layer 110. The first conductive layer 121 may include a metal, an alloy, a metal nitride, a silicide, transparent conductive oxide (TCO), etc. The metal may include, for example, gold (Au), aluminum (Al), silver (Ag), copper (Cu), platinum (Pt), nickel (Ni), tungsten (W), titanium (Ti), molybdenum (Mo), ruthenium (Ru), germanium (Ge), tantalum (Ta), hafnium (Hf), niobium (Nb), zirconium (Zr), or vanadium (V). The alloy may include, for example, aluminum neodymium (AlNd). The metal nitride may include, for example, a titanium nitride (TiN), an aluminum nitride (AlN), tantalum nitrides (TaN, Ta₂N, Ta₃N₅), or tungsten nitrides (W₂N, WN, WN₂). The silicide may include, for example, titanium silicide (TiSi, TiSi₂, Ti₅Si₃), vanadium silicides (VSi, VSi₂), iron silicide (FeSi₂), cobalt silicide (CoSi₂), platinum silicides (PtSi, Pt₂Si), nickel silicides (NiSi, NiSi₂, Ni₂Si), copper silicides (CuSi, CusSi), yttrium silicide (YSi), zirconium silicides (ZrSi, ZrSi₂), niobium silicides (NbSi, NbSi₂), molybdenum silicide (MoSi₂), palladium silicides (PdSi, Pd₂Si), erbium silicide (ErSi), ytterbium silicides (YbSi, YbSi₂), hafnium silicides (HfSi, HfSi₂), tantalum silicides (TaSi, TaSi₂), tungsten silicides (WSi, WSi₂), gemanium silicide (GeSi), osmium silicide (OsSi), iridium silicides (IrSi, IrSi₃), aluminum silicide (AISi), or ruthenium silicides (RuSi, Ru₂Si₃). The transparent conductive oxide may include, for example, indium tin oxide (ITO), indium tungsten oxide (IWO), indium zinc oxide (IZO), gallium doped zinc oxide (GZO), gallium indium zinc oxide (GIZO), or aluminum zinc oxide (AZO).

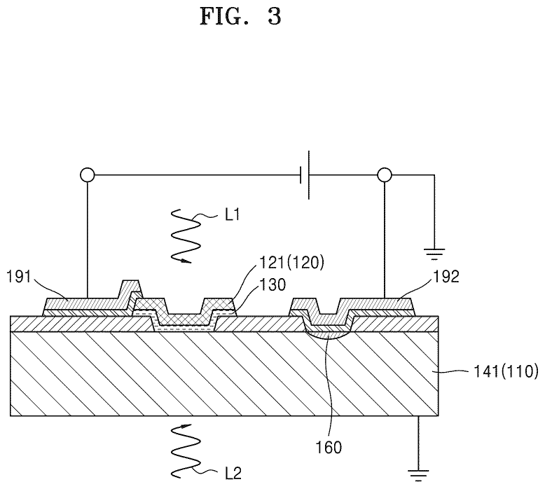

The first conductive layer 121 or the first semiconductor layer 110 may be a light incident side. For example, light (e.g., light L1 shown in FIG. 3) may enter the first conductive layer 121. In this case, the first conductive layer 121 may be formed of a transparent conductive oxide, or may have a small thickness allowing the incident light L1 to transmit through the first conductive layer 121. The thickness of the first conductive layer 121 may be about 100 nm or less. For example, the thickness of the first conductive layer 121 may be 50 nm or less or 5 nm or less. For example, light (e.g., light L2 shown in FIG. 3) may enter the first conductive layer 110. In this case, the first conductive layer 121 may have a thickness to prevent light from being transmitted therethrough. The light L2 entered the first semiconductor layer 110 may be reflected by the first conductive layer 121 and then again enter the first semiconductor layer 110, resulting in an increase of light detection efficiency.

According to a structure shown in FIG. 1, a part of the light L1 or light L2 may be absorbed in the first semiconductor layer 110, and another part may be absorbed in the first conductive layer 121. Photons absorbed in the first conductive layer 121 may generate photocurrent by an internal quantum emission effect. Photons absorbed in the first semiconductor layer 110 may generate photocurrent with high efficiency by interband transition. By the two mechanisms, a wide light absorption band and improved quantum efficiency may be implemented. Also, a short wavelength infrared (SWIR) band may be absorbed according to a Schottky barrier height (energy) between the first conductive layer 121 and the first semiconductor layer 110.

According to an embodiment, the conductive layer 120 may have a multilayer structure. For example, reference to FIG. 2, the conductive layer 120 may include the first conductive layer 121, and a second conductive layer 122 formed on the first conductive layer 121 and being transparent. The first conductive layer 121 may form a Schottky Junction structure together with the first semiconductor layer 110. The first conductive layer 121 may include a metal, an alloy, a metal nitride, a silicide, and the like. The metal may include, for example, Au, Al, Ag, Cu, Pt, Ni, W, Ti, Mo, Ru, Ge, Ta, Hf, Nb, Zr, or V. The alloy may include, for example, AlNd. The metal nitride may include, for example, TiN, AlN, TaN, Ta₂N, Ta₃N₅, W₂N, WN, or WN₂. The silicide may include, for example, TiSi, TiSi₂, Ti₅Si₃, VSi₂, FeSi₂, CoSi₂, PtSi, Pt₂Si, NiSi, NiSi₂, Ni₂Si, CusSi, YSi, ZrSi, NbSi₂, MoSi₂, PdSi, Pd₂Si, ErSi, YbSi, YbSi₂, ZrSi₂, HfSi, HfSi₂, TaSi, TaSi₂, NbSi, NbSi₂, ZrSi, ZrSi₂, VSi, VSi₂, WSi, WSi₂, GeSi, OsSi, IrSi, IrSi₃, AISi, CuSi, RuSi, or Ru₂Si₃. The second conductive layer 122 may be a transparent conductive layer having light transmittance and high electrical conductivity. For example, the second conductive layer 122 may include transparent conductive oxide (TCO) having transmittance with respect to light ranging from the visible light to infrared bands. The transparent conductive oxide may include, for example, ITO, IWO, IZO, GZO, GIZO, or AZO.

The first conductive layer 121 may have a work function that is different from that of the second conductive layer 122. The first conductive layer 121 is also referred to an interlayer metal layer. The work function of the first conductive layer 121 may be set by considering materials of the second conductive layer 122 and the first semiconductor layer 110 being adjacent to the first conductive layer 121 to lower the Schottky barrier height. The Schottky barrier height may refer to an energy barrier at an interface between the first conductive layer 121 and the first semiconductor layer 110 or between the second conductive layer 122 and the first semiconductor layer 110 in the Schottky junction. Carriers formed in the conductive layer 121 or the second conductive layer 122 by incident light may be required to pass the Schottky barrier height to move to the first semiconductor layer 110. For example, the work function of the first conductive layer 121 may be set such that a Schottky barrier height formed in the Schottky junction structure between the first conductive layer 121 and the first semiconductor layer 110 is lower than a Schottky barrier height in a case in which a Schottky junction structure is formed by two layers of the second conductive layer 122 and the first semiconductor layer 110. By lowering the Schottky barrier height, light having low energy may be detected.

The work function of the first conductive layer 121 may be set based on a material and conductive type (n type or p type) of the first conductive layer 110 and a work function of the second conductive layer 122. For example, according to the first semiconductor layer 110 being an n type, the work function of the first conductive layer 121 may satisfy requirements of the following Equation (1), and a Schottky barrier height may be expressed by the following Equation (2). For example, according to the first semiconductor layer 110 being a p type, the work function of the first conductive layer 121 may satisfy requirements of the following Equation (3), and a Schottky barrier height may be expressed by the following Equation (4). In Equations (1), (2), (3), and (4), OM is a work function of the second conductive layer 122, φ_{Mi} is a work function of the first conductive layer 121, xs is electron affinity of the first semiconductor layer 110, and E_{g} is bandgap energy of the first semiconductor layer 110.

$${φ}_{M} > {φ}_{Mi} > {χ}_{S} \qquad Equation ( 1 )$$

$${φ}_{B} = {φ}_{Mi} - {χ}_{S} \qquad Equation ( 2 )$$

$${φ}_{M} < {φ}_{Mi} < {χ}_{S} + {E}_{g} \qquad Equation ( 3 )$$

$${φ}_{B} = {E}_{g} - ( {φ}_{Mi} - {χ}_{S} ) \qquad Equation ( 4 )$$

For example, the second conductive layer 122 may be ITO and the first semiconductor layer 110 may be n-Ge. In this case, the first conductive layer 121 may be, for example, TiN. However, this is only an example, and the disclosure is not limited to this example. The first conductive layer 121 may be formed of a metal nitride, such as AlN, TaN, Ta₂N, Ta₃N₅, W₂N, WN, or WN₂, or may be formed of Ta, Al, Ti, Mo, V, Mn, Nb, or Mo having a relatively small work function. For example, the second conductive layer 122 may be formed of ITO and the first semiconductor layer 110 may be formed of p-Ge. In this case, the first conductive layer 121 may be formed of, for example, Cu or Ni. The first conductive layer 121 may have a thickness to transmit light entered the second conductive layer 122. The thickness of the first conductive layer 121 may be about 100 nm or less. For example, the thickness of the first conductive layer 121 may be 50 nm or less or 5 nm or less. The second conductive layer 122 may have a thickness of about 100 nm or less, like the first conductive layer 121. For example, the thickness of the second conductive layer 122 may be 50 nm or less or 5 nm or less.

Internal quantum efficiency of the first conductive layer 121 may be influenced by the thickness of the first conductive layer 121. The greater thickness of the first conductive layer 121, the lower generation efficiency of photoexcited carriers, and accordingly, a large amount of photons may be reflected from a surface of the first conductive layer 121, resulting in deterioration of the internal quantum efficiency. According to the structure including the first and second conductive layers 121 and 122 and the first semiconductor layer 110 as shown in FIG. 2, it may be possible to reduce the thickness of the first conductive layer 121, and by appropriately selecting work functions and energy levels of the first semiconductor layer 110, the first conductive layer 121 and the second conductive layer 122, photocurrent may be generated in a wide range of the NIR to SWIR bands with high quantum efficiency. According to the structure shown in FIG. 2, a part of incident light may be absorbed in the first conductive layer 121 and the second conductive layer 122, and another part may be absorbed in the first semiconductor layer 110. Photons absorbed in the first conductive layer 121 and the second conductive layer 122 may generate photocurrent by the internal quantum emission effect. Photons absorbed in the first semiconductor layer 110 may generate photocurrent by a photovoltaic effect. By the two mechanisms, a wide light absorption range of the NIR to SWIR bands and improved quantum efficiency may be implemented.

In a photodetector using a Schottky barrier, the structure of the Schottky barrier may be very thin and may exhibit a sharply inclined energy band diagram due to energy band bending. Consequently, quantum mechanical tunneling may induce leakage current. This phenomenon may cause carriers having lower energy than a Schottky barrier height to leak through the Schottky barrier, due to field emission generated between the first conductive layer 121 and the first semiconductor layer 110. These leakage carriers may correspond to dark current that flows in the absence of incident light. The dark current may generate noise in the photodetector, an image sensor incorporating the photodetector, etc. Accordingly, to improve performance of the photodetector and the image sensor, dark current may need to be suppressed as much as possible.

In consideration of this, referring to FIGS. 1 and 2, the photodetector 100 according to an embodiment of the disclosure may include the tunneling barrier layer 130 between the conductive layer 120 and the first semiconductor layer 110. The tunneling barrier layer 130 may increase the thickness of the Schottky barrier structure while having little or no influence on the Schottky barrier height, thereby reducing or preventing leakage current caused by quantum mechanical tunneling. To have less influence on the Schottky barrier height, the tunneling barrier layer 130 may be formed of a material of which a conduction band energy level is similar to the electron affinity of the first semiconductor layer 110. That is, the tunneling barrier layer 130 may be formed of a material having a similar conduction band energy level to that of the first semiconductor layer 110. For example, a difference between the conduction band energy level of the tunneling barrier layer 130 and the conduction band energy level of the first semiconductor layer 110, that is, a difference in electron affinity may be 0.5 eV or less.

In addition, to reduce or prevent dark current resulting from separation of electron-hole pairs induced by low-energy light, bandgap energy of the tunneling barrier layer 130 may be greater than that of the first semiconductor layer 110. For example, the bandgap energy of the tunneling barrier layer 130 may be greater than 2 eV. The tunneling barrier layer 130 may be formed of a metal oxide semiconductor having a wide bandgap energy (e.g., a bandgap energy greater than 2 eV). According to an embodiment, the metal oxide semiconductor may include, for example, TiO₂, SnO₂, ZnO, WO₃, Nb₂O₅, BaSnO₃, Zn₂SnO₄, SrTiO₃, BaTiO₃, Zn₂Ti₃O₈, SiO₂, Al₂O₃, HfO₂, MgO, MoO₃, Fe₃O₃, Ta₂O₅, TaON, or In₂O₃. According to an embodiment, the metal oxide semiconductor may include TiO₂, TiO₂₋ₓ(0<x<1), TiO, Ti₂O, Ti₃O, Ti₂O₃, or TiₙO₂ₙ₋₁ (n is an integer of 3 to 9). According to an embodiment, the tunneling barrier layer 130 may include a metal oxide and a silicon oxide.

The thickness of the tunneling barrier layer 130 may be set to reduce or prevent dark current. The thickness of the tunneling barrier layer 130 may be within 30 nm. At the thickness of the tunneling barrier layer 130 being greater than 30 nm, carriers may be difficult to pass through the tunneling barrier layer 130 under normal conditions. To secure mobility of carriers, the thickness of the tunneling barrier layer 130 may be, for example, within 10 nm.

Hereinafter, various implementation examples of the photodetector 100 and operations thereof will be described. The various implementation examples of the photodetector 100, which will be described below, may be embodiments based on various types of the first semiconductor layer 110 and connection forms between electrodes and the photodetector 100.

FIG. 3 is a schematic configuration view of an implementation example of the photodetector 100 according to an embodiment shown in FIG. 1. Referring to FIG. 3, the first semiconductor layer 110 may be provided as, for example, a p- or n-doped Ge substrate, for example, an n-doped n-Ge substrate 141. The tunneling barrier layer 130 and the first conductive layer 121 may be sequentially positioned on the n-Ge substrate 141. As a top light incident structure in which light L1 is incident from above the first conductive layer 121, the first conductive layer 121 may be formed of a transparent metal oxide with high light transmittance, for example, ITO. As a bottom light incident structure in which light is incident from below the n-Ge substrate 141, the first conductive layer 121 may be formed of a thick metal or a thick metal nitride through which light does not pass. A first electrode 191 and a second electrode 192 may be formed to apply an electrical signal to the Schottky junction structure on the n-Ge substrate 141 or to measure an electrical signal generated from the Schottky junction structure. The first electrode 191 may be in contact with the first conductive layer 121. The first electrode 191 may be in direct physical contact with the first conductive layer 121, or may be electrically connected to the first conductive layer 121, without direct physical contact between the first electrode 191 and the first conductive layer 121. The second electrode 192 may be in contact with the n-Ge substrate 141. The second electrode 192 may be in direct physical contact with the n-Ge substrate 141, or may be electrically connected to the n-Ge substrate 141, without direct physical contact between the second electrode 192 and the n-Ge substrate 141. The first and second electrodes 191 and 192 may have various shapes capable of electrically contacting the first conductive layer 121 and the n-Ge substrate 141 while securing an opening to which light is incident through the first conductive layer 121. For example, at a region of the n-Ge substrate 141, an ohmic contact region 160 doped with an n-type dopant at a higher concentration than other regions may be formed, and the second electrode 192 may be formed in such a way as to be in contact with the ohmic contact region 160.

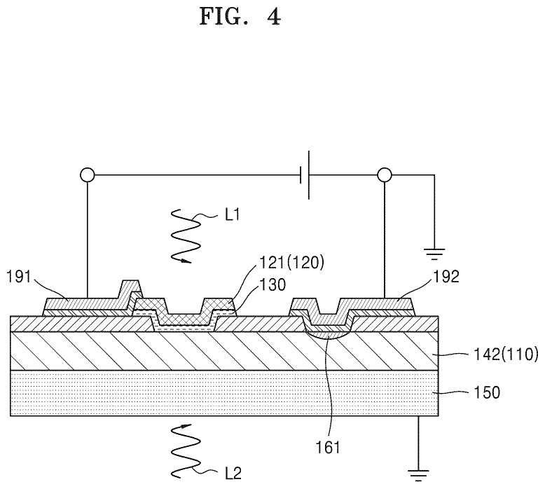

FIG. 4 is a schematic configuration view of an implementation example of the photodetector 100 according to an embodiment shown in FIG. 1. Referring to FIG. 4, the first semiconductor layer 110 may be formed on, for example, a semiconductor substrate 150. The first semiconductor layer 110 may be an intrinsic-Ge (i-Ge) layer, an amorphous-Ge layer, an epitaxially grown Ge layer, or a GeₓSn₁₋ₓ (0<x<1) layer. The first semiconductor layer 110 may be doped with one of a p-type and an n-type. For example, a doping concentration of p-Ge may range from 10¹³/cm³ to 10¹⁸/cm³, and a p-type dopant may be B, Al, Ga, In, or Te. For example, a doping concentration of n-Ge may range from 10¹³/cm³ to 10¹⁸/cm³, and an n-type dopant may be P, As, or Sb.

For example, according to an embodiment, the first semiconductor layer 110 may be provided in a form of an n-doped n-Ge layer 142. The semiconductor substrate 150 may be, for example, a p-Si substrate or a n-Si substrate. The tunneling barrier layer 130 and the first conductive layer 121 may be sequentially positioned on the n-Ge layer 142. In the case of the top light incident structure in which light L1 is incident from above the first conductive layer 121, the first conductive layer 121 may be formed of a transparent metal oxide with high light transmittance, for example, ITO. In the case of the bottom light incident structure in which light is incident from below the semiconductor layer 150, the first conductive layer 121 may be formed of a thick metal or a thick metal nitride through which light does not pass. The first electrode 191 and the second electrode 192 may be formed to apply an electrical signal to a Schottky junction structure on the n-Ge layer 142 or to measure an electrical signal generated from the Schottky junction structure. The first electrode 191 may be in contact with the first conductive layer 121. The first electrode 191 may be in direct physical contact with the first conductive layer 121, or may be electrically connected to the first conductive layer 121, without direct physical contact between the first electrode 191 and the first conductive layer 121. The second electrode 192 may be in contact with the n-Ge layer 142. The second electrode 192 may be in direct physical contact with the n-Ge layer 142, or may be electrically connected to the n-Ge layer 142, without direct physical contact between the second electrode 192 and the n-Ge layer 142. For example, at a region of the n-Ge layer 142, an ohmic contact region 161 doped with an n-type dopant at a higher concentration than other regions may be formed, and the second electrode 192 may be formed in such a way as to be in contact with the ohmic contact region 161.

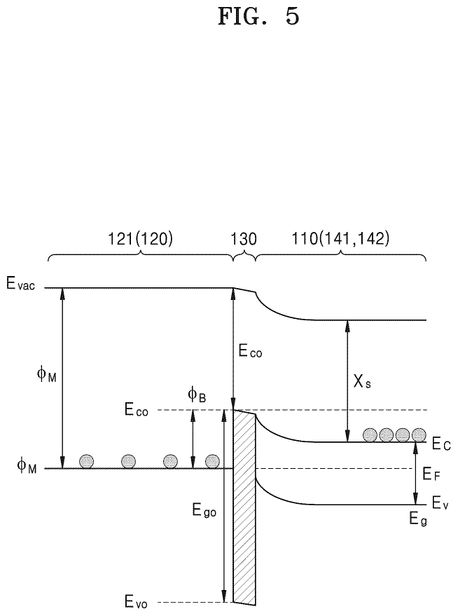

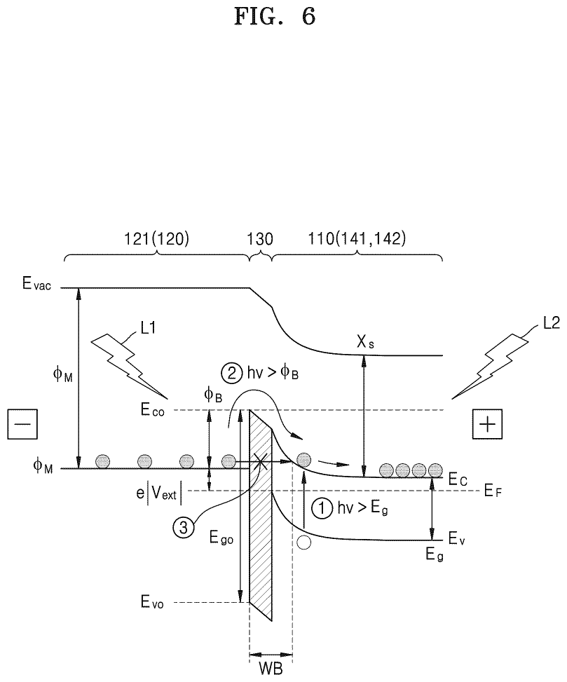

FIG. 5 is an energy band diagram of the implementation examples of the photodetector 100 shown in FIGS. 3 and 4 while no bias voltage is applied. FIG. 6 is an energy band diagram of the implementation examples of the photodetector 100 shown in FIGS. 3 and 4 while a reverse bias voltage is applied. Symbols shown in FIGS. 5 and 6 may be defined as follows.
φ_{M}: work function of the first conductive layer 121
φ_{B}: Schottky barrier height
E_{vac}: energy level of vacuum
E_{co}: conduction band energy level of the tunneling barrier layer 130
Eᵥₒ: valance band energy level of the tunneling barrier layer 130
E_{go}: bandgap energy of the tunneling barrier layer 130
E_{c}: conduction band energy level of the first conductive layer 110
Eᵥ: valance band energy level of the first semiconductor layer 110
E_{F}: Fermi energy level of the first semiconductor layer 110
E_{g}: bandgap energy of the first semiconductor layer 110
Xₛ: electron affinity of the first semiconductor layer 110
e|Vext|: energy by a reverse bias voltage
hv: energy of incident light

For example, in FIGS. 5 and 6, the first semiconductor layer 110 may be formed of n-Ge, the first conductive layer 121 may be formed of ITO, and the tunneling barrier layer 130 may be formed of TiO₂. In this case, bandgap energy E_{g} of Ge may be 0.67 eV, electron affinity Xₛ of Ge may be 4.0 eV, and a work function OM of ITO may be 4.7 eV. Schottky barrier height (φB)=φ_{M}−X_{S}=4.7−4.0=0.7 eV.

According to application of a reverse bias voltage, the Fermi energy level of the first semiconductor layer 110 may be lowered by energy e|Vext| provided by the reverse bias voltage, as shown in FIG. 6. Because Ge has lower bandgap energy than that of silicon Si, Ge may easily absorb NIR to SWIR light. Accordingly, while energy of incident light is higher than bandgap energy of the first semiconductor layer 110 (hv>E_{g}), as indicated by reference numeral (1) in FIG. 6, photocurrent by interband transition may be detected. Also, as indicated by reference numeral (2) in FIG. 6, while energy of incident light is higher than the Schottky barrier height PB formed between the first conductive layer 121 and the first semiconductor layer 110 (hv>φB), partial light absorption may occur in the first conductive layer 121, and thus, hot carriers may be formed due to the internal quantum emission effect to cause photocurrent to flow.

In FIG. 6, in a case in which there is no tunneling barrier layer 130, some (that is, electrons) of majority carriers having lower energy than the Schottky barrier height may penetrate the Schottky barrier by quantum mechanical tunneling to move from the first conductive layer 121 to the first semiconductor layer 110, although there is no incident light, thereby generating dark current.

According to an embodiment, the tunneling barrier layer 130 may be positioned between the first conductive layer 121 and the semiconductor layer 110. Electron affinity Xₛ of Ge forming the first semiconductor layer 110 may be 4.0 eV. A conduction band energy level E_{co} of TiO₂ forming the tunneling barrier layer 130 may be −4.0 eV that is substantially equal to that of the first semiconductor layer 110. Accordingly, the tunneling barrier layer 130 may have little influence on the Schottky barrier height between the first conductive layer 121 and the first semiconductor layer 110. Meanwhile, the Schottky barrier may increase in thickness by the tunneling barrier layer 130, as indicated by reference numeral WB in FIG. 6. Accordingly, as indicated by reference numeral (3) in FIG. 6, tunneling of electrons may be reduced or prevented, thereby reducing or preventing dark current.

Bandgap energy E_{g} of Ge forming the first semiconductor layer 110 may be 0.67 eV. Because a valence band energy level Eᵥₒ of TiO₂ forming the tunneling barrier layer 130 is-7.2 eV and a conduction band energy level E_{co} of TiO₂ is −4.0 eV, bandgap energy E_{go} of TiO₂ forming the tunneling barrier layer 130 may be Eᵥₒ−E_{co}=7.2-4.0=3.2 eV, which is greater than the bandgap energy E_{g} of Ge. Accordingly, because the tunneling barrier layer 130 formed of TiO₂ does not absorb light in the infrared band, the tunneling barrier layer 130 may be appropriately used as a tunneling barrier layer that prevents dark current.

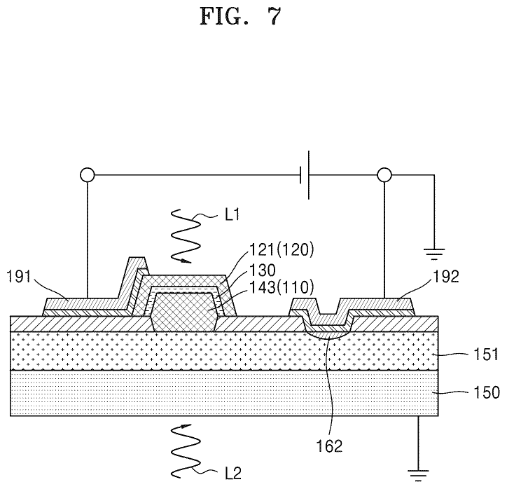

FIG. 7 is a schematic configuration view of an implementation example of the photodetector 100 according to an embodiment shown in FIG. 1. Referring to FIG. 7, the semiconductor substrate 150, and a second semiconductor layer 151 formed on the semiconductor substrate 150 are shown. The first semiconductor layer 110 may be formed on the second semiconductor layer 151. The semiconductor substrate 150 and the second semiconductor layer 151 may be formed of the same material. The semiconductor substrate 150 and the second semiconductor layer 151 may be doped with different conductive types. The semiconductor substrate 150 may be doped with any one of an n type and a p type, and the second semiconductor layer 151 may be doped with another one of the n type and p type. The semiconductor substrate 150 may be a Si substrate doped with a first type, for example, a p type. The second semiconductor layer 151 may be a Si layer doped with a second type, for example, an n type. The first semiconductor layer 110 may be an intrinsic-Ge (i-Ge) layer, an amorphous-Ge layer, an epitaxially grown Ge layer, or a GeₓSn₁₋ₓ (0<x<1) layer. The first semiconductor layer 110 may be doped with one of a p-type and an n-type. For example, a doping concentration of p-Ge may range from 10¹³/cm³ to 10¹⁸/cm³, and a p-type dopant may be B, Al, Ga, In, or Te. For example, a doping concentration of n-Ge may range from 10¹³/cm³ to 10¹⁸/cm³, and an n-type dopant may be P, As, or Sb.

For example, according to an embodiment, the first semiconductor layer 110 may be a n-Ge layer 143 including n-Ge. The tunneling barrier layer 130 and the first conductive layer 121 may be sequentially positioned on the n-Ge layer 143. As the top light incident structure in which light L1 is incident from above the first conductive layer 121, the first conductive layer 121 may be formed of a transparent metal oxide with high light transmittance, for example, ITO. As the bottom light incident structure in which light is incident from below the semiconductor layer 150, the first conductive layer 121 may be formed of a thick metal or a thick metal nitride through which light does not pass. The first electrode 191 and the second electrode 192 may be formed to apply an electrical signal to a Schottky junction structure on the second semiconductor layer 151 or to measure an electrical signal generated from the Schottky junction structure. The first electrode 191 may be in contact with the first conductive layer 121. The first electrode 191 may be in direct physical contact with the first conductive layer 121, or may be electrically connected to the first conductive layer 121, without direct physical contact between the first electrode 191 and the first conductive layer 121. The second electrode 192 may be in contact with the second semiconductor layer 151. The second electrode 192 may be in direct physical contact with the second semiconductor layer 151, or may be electrically connected to the second semiconductor layer 151, without direct physical contact between the second electrode 192 and the second semiconductor layer 151. For example, at a region of the second substrate layer 151, an ohmic contact region 162 doped with an n-type dopant at a higher concentration than other regions may be formed, and the second electrode 192 may be formed in such a way as to be in contact with the ohmic contact region 162.

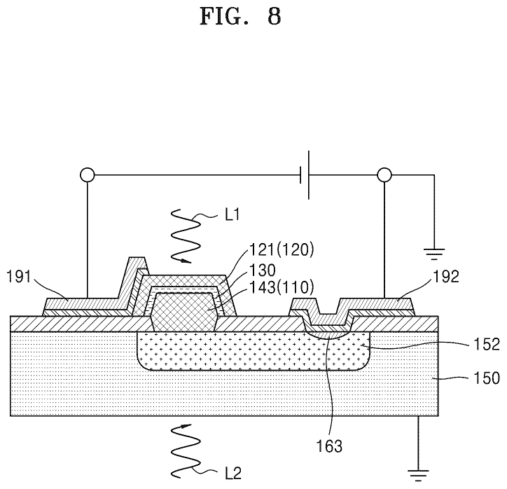

FIG. 8 is a schematic configuration view of an implementation example of the photodetector 100 according to an embodiment shown in FIG. 1. The implementation example of the photodetector 100 shown in FIG. 8 may be different from the implementation example of the photodetector 100 shown in FIG. 7 in that a doping region 152 is provided on the semiconductor substrate 150 and the first semiconductor layer 143 is formed on the doping region 152. Accordingly, the above description given with reference to FIG. 7 may be applied to the implementation example of FIG. 8 as long as there is no contradiction, and only differences between the implementation example of FIG. 8 and the implementation example of FIG. 7 will be briefly described below. Referring to FIG. 8, the semiconductor substrate 150 and the doping region 152 may be doped with different conductive types. The semiconductor substrate 150 may be doped with any one of an n type and a p type, and the doping region 152 may be doped with another one of the n type and p type. The semiconductor substrate 150 may be a Si substrate doped with, for example, a p type. The doping region 152 may be a region doped with, for example, an n type, that is, a n-well. The first semiconductor layer 110 may be a n-Ge layer 143 including Ge, for example, n-Ge. The tunneling barrier layer 130 and the first conductive layer 121 may be sequentially positioned on the n-Ge layer 143. The first electrode 191 may be in contact with the first conductive layer 121. The second electrode 192 may be in contact with the doping region 152. For example, at a region of the doping region 152, an ohmic contact region 163 doped with an n-type dopant at a higher concentration than other regions may be formed, and the second electrode 192 may be formed in such a way as to be in contact with the ohmic contact region 163.

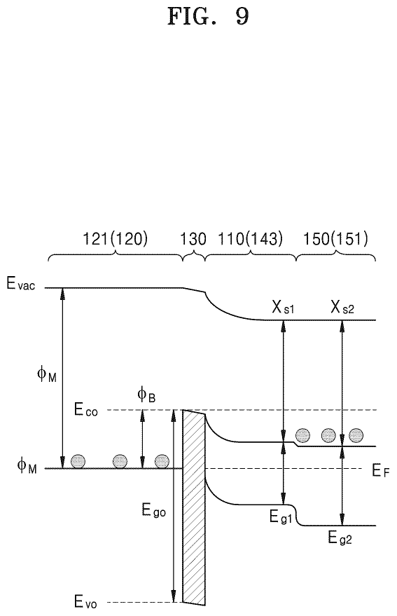

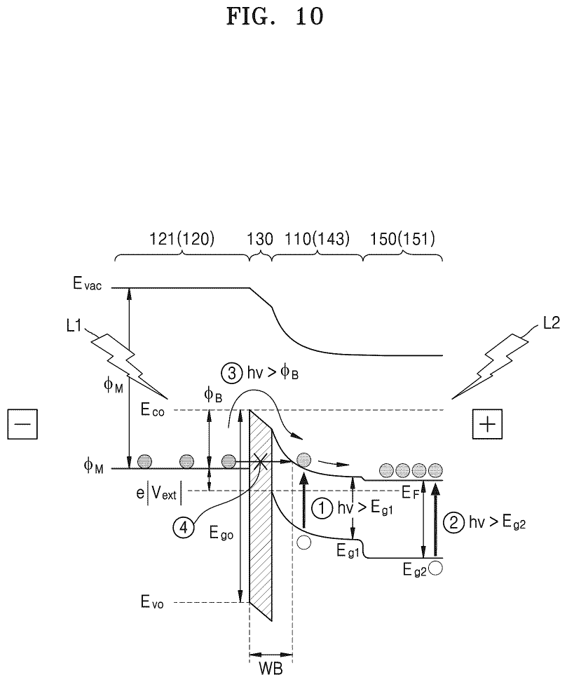

FIG. 9 is an energy band diagram of the implementation examples of the photodetector 100 shown in FIGS. 7 and 8 while no bias voltage is applied. FIG. 10 is an energy band diagram of the implementation examples of the photodetector 100 shown in FIGS. 7 and 8 while a reverse bias voltage is applied. Symbols shown in FIGS. 9 and 10 may be defined as follows.

φM: work function of the first conductive layer 121

φB: Schottky barrier height

E_{vac}: energy level of vacuum

E_{co}: conduction band energy level of the tunneling barrier layer 130

Eᵥₒ: valance band energy level of the tunneling barrier layer 130

E_{go}: bandgap energy of the tunneling barrier layer 130

E_{F}: Fermi energy level of the n-Ge layer 143

E_{g1}: bandgap energy of the n-Ge layer 143

E_{g2}: bandgap energy of the semiconductor substrate 150

Xₛ₁: electron affinity of the n-Ge layer 143

Xₛ₂: electron affinity of the semiconductor substrate 150

e|Vext|: energy by a reverse bias voltage

hv: energy of incident light

For example, in FIGS. 9 and 10, the first conductive layer 121 may be formed of ITO, the tunneling barrier layer 130 may be formed of TiO₂, and the semiconductor layer 150 may be formed of Si. In this case, bandgap energy E_{g} of Ge may be 0.67 eV, electron affinity Xₛ₁ of Ge may be 4.0 eV, electron affinity Xₛ₂ of silicon Si may be 4.05 eV, and a work function OM of ITO may be 4.7 eV. Schottky barrier height (φB)=φM−X_{S1}=4.7−4.0=0.7 eV.

According to application of a reverse bias voltage, the Fermi energy level E_{F} of the n-Ge layer 143 may be lowered by energy e|Vext| provided by the reverse bias voltage, as shown in FIG. 10. Because Ge has lower bandgap energy than that of silicon Si, Ge may easily absorb NIR to SWIR light. Accordingly, while energy of incident light is greater than bandgap energy of the n-Ge layer 143 (hv>E_{g1}), as indicated by reference numeral \textcircled{1} in FIG. 10, photocurrent by interband transition may be detected. Also, while visible light is incident, energy of the incident light may be higher than the bandgap energy of the semiconductor substrate 150 (hv>E_{g2}), as indicated by reference numeral \textcircled{2} in FIG. 10. In this case, photocurrent by interband transition in the semiconductor substrate 150 and/or the second semiconductor layer 151 (or the doping region 152) may be detected. Also, as indicated by reference numeral \textcircled{3} in FIG. 10, while energy of incident light is higher than the Schottky barrier height OB formed between the first conductive layer 121 and the first semiconductor layer 110 (hv>φB), partial light absorption may occur in the first conductive layer 121, and thus, hot carriers may be formed by the internal quantum emission effect to cause photocurrent to flow. Therefore, according to the implementation examples of the photodetector 100 shown in FIGS. 7 and 8, light in the visible light band, as well as the NIR and SWIR bands may be detected. Also, by adopting the tunneling barrier layer 130, the Schottky barrier may increase in thickness by the tunneling barrier layer 130, as indicated by reference numeral WB in FIG. 10, without having little influence on the Schottky barrier height between the first conductive layer 121 and the first semiconductor layer 110. Accordingly, as indicated by reference numeral (4) in FIG. 10, tunneling of electrons may be reduced or prevented, thereby reducing or preventing dark current.

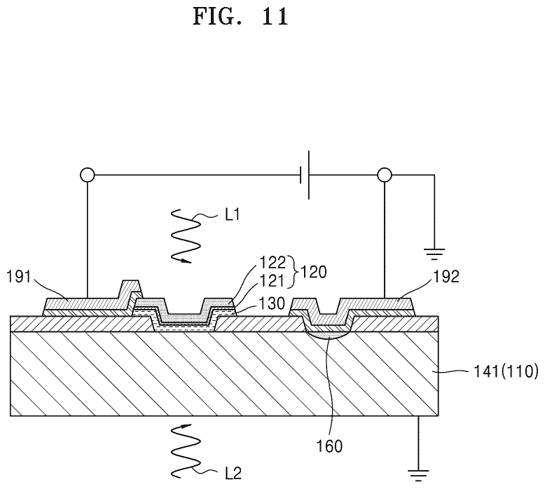

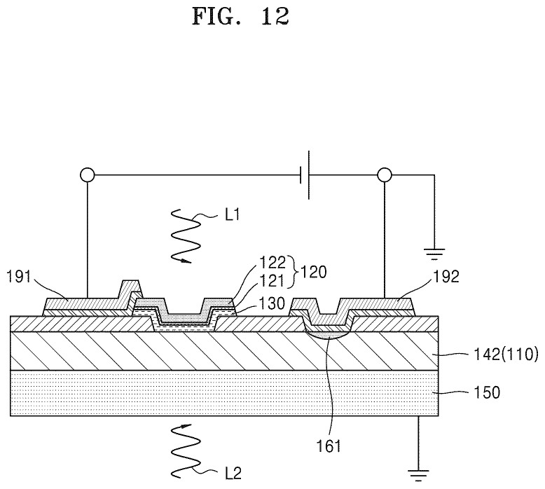

FIG. 11 is a schematic configuration view of an implementation example of the photodetector 100 according to an embodiment shown in FIG. 2. The implementation example shown in FIG. 11 may be different from the implementation example shown in FIG. 3 in that the conductive layer 120 includes the first conductive layer 121 and the second conductive layer 122. FIG. 12 is an implementation example of the photodetector 100 according to an embodiment shown in FIG. 2. The implementation example shown in FIG. 12 may be different from the implementation example shown in FIG. 4 in that the conductive layer 120 includes the first conductive layer 121 and the second conductive layer 122. Accordingly, the above description given with reference to FIGS. 3 and 4 will also be applied to the implementation examples of FIGS. 11 and 12 as long as there is no contradiction, like components will be assigned like reference numerals, and a repeated explanation will be omitted.

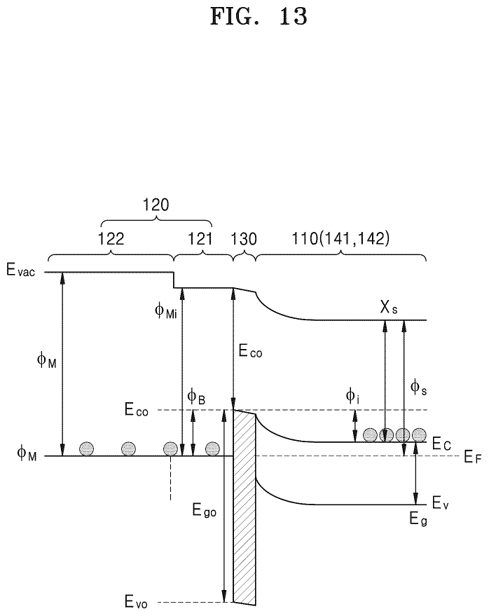

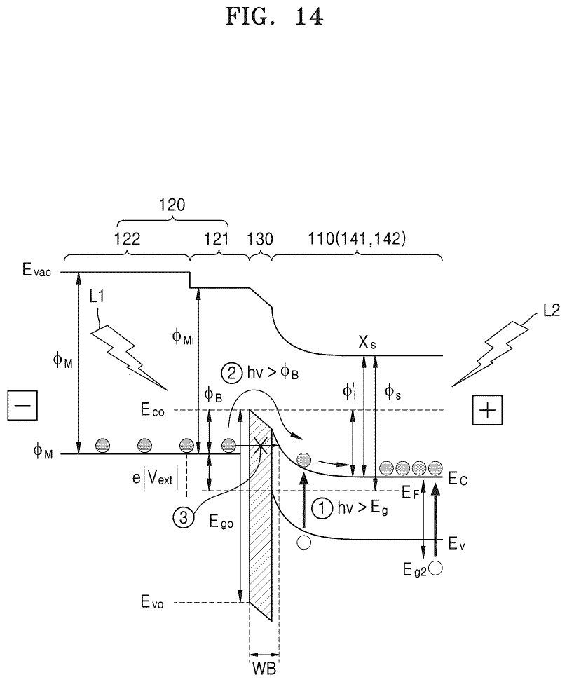

FIG. 13 is an energy band diagram of the implementation examples of the photodetector shown in FIGS. 11 and 12 while no bias voltage is applied. FIG. 14 is an energy band diagram of the implementation examples of the photodetector 100 shown in FIGS. 11 and 12 while a reverse bias voltage is applied. Symbols shown in FIGS. 13 and 14 may be defined as follows.

φ_{Mi}: work function of the first conductive layer 121

φ_{M}: work function of the second conductive layer 122

φ_{B}: Schottky barrier height

E_{vac}: energy level of vacuum

E_{co}: conduction band energy level of the tunneling barrier layer 130

Eᵥₒ: valance band energy level of the tunneling barrier layer 130

E_{go}: bandgap energy of the tunneling barrier layer 130

E_{c}: conduction band energy level of the first semiconductor layer 110

Eᵥ: valance band energy level of the first semiconductor layer 110

E_{F}: Fermi energy level of the first semiconductor layer 110

E_{g}: bandgap energy of the first semiconductor layer 110

Xₛ: electron affinity of the first semiconductor layer 110

φₛ: work function of the first semiconductor layer 110

φᵢ: built in potential of the first semiconductor layer 110 while no bias voltage is applied

φ_{i′}: built in potential of the first semiconductor layer 110 while a reverse bias voltage is applied

e|Vext|: energy by a reverse bias voltage

hv: energy of incident light

For example, in FIGS. 11 and 12, the first semiconductor layer 110 may be formed of n-Ge, the first conductive layer 121 may be formed of TiN, the second conductive layer 122 may be formed of ITO, and the tunneling barrier layer 130 may be formed of TiO₂. In this case, bandgap energy of Ge may be 0.67 eV, electron affinity Xₛ of Ge may be 4.0 eV, a work function φ_{Mi} of TiN may be 4.5 eV, and a work function QM of ITO may be 4.7 eV. Accordingly, the condition φ_{M}>φ_{Mi}>Xₛ of the above Equation (1) may be satisfied. Schottky barrier height ((B)=φ_{Mi}−X_{S}=4.5-4.0=0.5 eV. The Schottky barrier height OB may be lower than a Schottky barrier height 0.7 eV at an ITO/n-GE interface as described above. Because a conduction band energy level of TiO₂ is substantially equal to a conduction band energy level of n-Ge, the tunneling barrier layer 130 may have little influence on the Schottky barrier height.

According to application of a reverse bias voltage, the Fermi energy level E_{F} of the first semiconductor layer 110 may be lowered by energy e|Vext| provided by the reverse bias voltage, as shown in FIG. 14. Because Ge has lower bandgap energy than that of silicon Si, Ge may easily absorb NIR to SWIR light. Accordingly, while energy of incident light is greater than bandgap energy of the first semiconductor layer 110 (hv>E_{g}), as indicated by reference numeral 1 in FIG. 14, photocurrent by interband transition may be detected. Also, as indicated by reference numeral (2) in FIG. 14, while energy of incident light is higher than the Schottky barrier height OB formed between the first conductive layer 121 and the first semiconductor layer 110 (hv>φB), partial light absorption may occur in the conductive layer 120, and thus, hot carriers may be formed by the internal quantum emission effect to cause photocurrent to flow. Because photocurrent is generated by the interband transition and internal quantum emission effect, NIR or SWIR having relatively low energy may be effectively detected. Also, by adopting the tunneling barrier layer 130, tunneling of electrons may be reduced or prevented, as indicated by reference numeral 3) in FIG. 14, without having little influence on the Shottky barrier height between the conductive layer 120 and the first semiconductor layer 110, thereby reducing or preventing dark current.

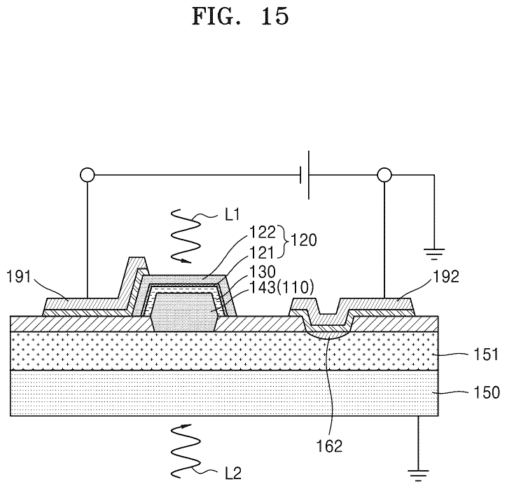

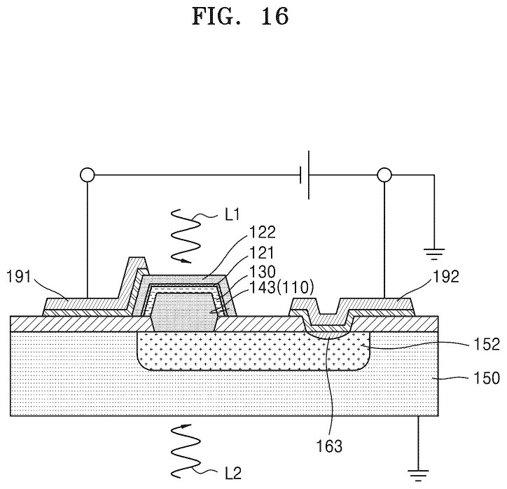

FIG. 15 shows an implementation example of the photodetector 100 according to an embodiment shown in FIG. 2. The implementation example shown in FIG. 15 may be different from the implementation example shown in FIG. 7 in that the conductive layer 120 includes the first conductive layer 121 and the second conductive layer 122. FIG. 16 shows an implementation example of the photodetector 100 according to an embodiment shown in FIG. 2. The implementation example shown in FIG. 16 may be different from the implementation example shown in FIG. 8 in that the conductive layer 120 includes the first conductive layer 121 and the second conductive layer 122. Accordingly, the above description given with reference to FIGS. 7 and 8 will also be applied to the implementation examples of FIGS. 15 and 16 as long as there is no contradiction, like components will be assigned like reference numerals, and a repeated explanation will be omitted.

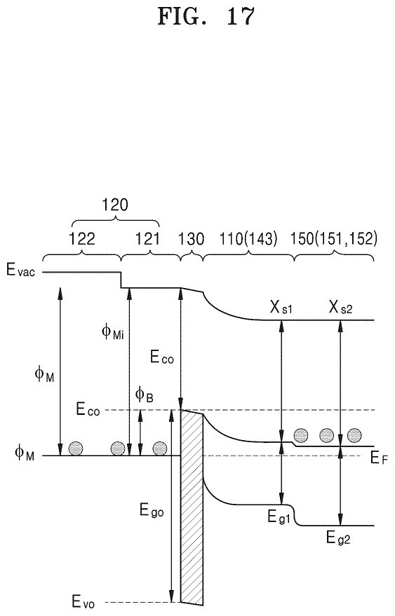

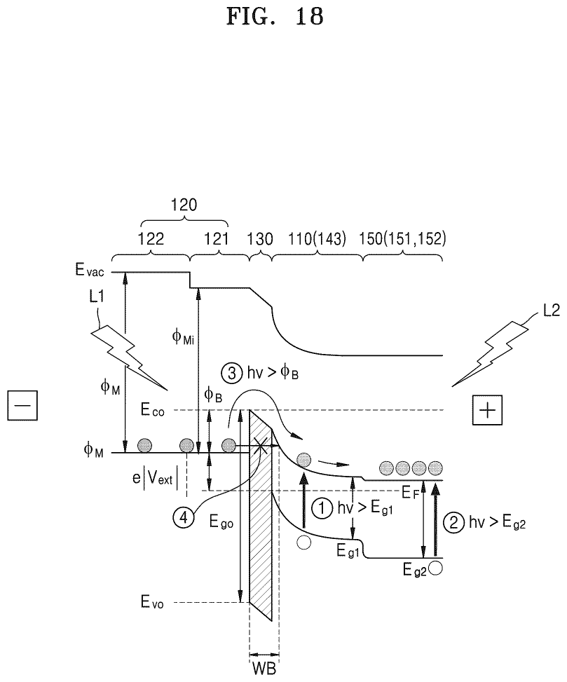

FIG. 17 is an energy band diagram of the implementation examples of the photodetector 100 shown in FIGS. 15 and 16 while no bias voltage is applied. FIG. 18 is an energy band diagram of the implementation examples of the photodetector 100 shown in FIGS. 15 and 16 while a reverse bias voltage is applied. Symbols shown in FIGS. 17 and 18 may be defined as follows.

φ_{Mi}: work function of the first conductive layer 121

φ_{M}: work function of the second conductive layer 122

φ_{B}: Schottky barrier height

E_{vac}: Energy level of vacuum

E_{co}: conduction band energy level of the tunneling barrier layer 130

Eᵥₒ: valance band energy level of the tunneling barrier layer 130

E_{go}: bandgap energy of the tunneling barrier layer 130

E_{F}: Fermi energy level of the first semiconductor layer 110

E_{g1}: bandgap energy of the first semiconductor layer 110

E_{g2}: bandgap energy of the semiconductor substrate 150

Xₛ₁: electron affinity of the first semiconductor layer 110

Xₛ₂: electron affinity of the semiconductor substrate 150

e|Vext|: energy by a reverse bias voltage

hv: energy of incident light

For example, in FIGS. 17 and 18, the first semiconductor layer 110 may be formed of n-Ge, the first conductive layer 121 may be formed of TiN, the second conductive layer 122 may be formed of ITO, the tunneling barrier layer 130 may be formed of TiO₂, and the semiconductor substrate 150 may be formed of Si. In this case, bandgap energy E_{g1} of Ge may be 0.67 eV, electron affinity Xₛ₁ of Ge may be 4.0 eV, electron affinity Xₛ₂ of silicon Si may be 4.05 eV, a work function (Mi of TiN may be 4.5 eV, and a work function QM of ITO may be 4.7 eV. Accordingly, the condition φ_{M}>φ_{Mi}>Xₛ of the above Equation (1) may be satisfied. Schottky barrier height ((B)=φ_{Mi}−X_{S}=4.5−4.0=0.5 eV. The Schottky barrier height OB may be lower than a Schottky barrier height 0.7 eV at an ITO/n-GE interface as described above. Because a conduction band energy level of TiO₂ is substantially equal to the conduction band energy level of n-Ge, the tunneling barrier layer 130 may have little influence on the Schottky barrier height.

According to application of a reverse bias voltage, the Fermi energy level E_{F} of the n-Ge layer 143 may be lowered by energy e|Vext| provided by the reverse bias voltage, as shown in FIG. 18. Because Ge has lower bandgap energy than that of silicon Si, Ge may easily absorb NIR to SWIR light. Accordingly, while energy of incident light is greater than bandgap energy of the n-Ge layer 143 (hv>E_{g1}), as indicated by reference numeral \textcircled{1} in FIG. 18, photocurrent by interband transition may be detected. Also, while visible light is incident, energy of the incident light may be greater than the bandgap energy of the semiconductor substrate 150 (hv>E_{g2}), as indicated by reference numeral \textcircled{2} in FIG. 18. In this case, photocurrent by interband transition in the semiconductor substrate 150 and/or the second semiconductor layer 152 (or the doping region 152) may be detected. Also, as indicated by reference numeral \textcircled{3} in FIG. 18, while energy of incident light is greater than the Schottky barrier height OB formed between the first conductive layer 121 and the first semiconductor layer 110 (hv>φB), partial light absorption may occur in the first conductive layer 121, and thus, hot carriers may be formed by the internal quantum emission effect to cause photocurrent to flow. According to the implementation examples of the photodetector 100 shown in FIGS. 15 and 16, light in the visible light band, as well as the NIR and SWIR bands may be detected. Also, by adopting the tunneling barrier layer 130, the Schottky barrier may increase in thickness by the tunneling barrier layer 130, as indicated by reference numeral WB in FIG. 18, without having little influence on the Schottky barrier height between the first conductive layer 121 and the first semiconductor layer 110. Accordingly, as indicated by reference numeral \textcircled{4} in FIG. 18, tunneling of electrons may be reduced or prevented, thereby reducing or preventing dark current.

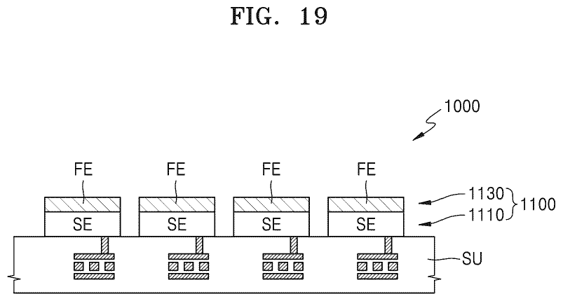

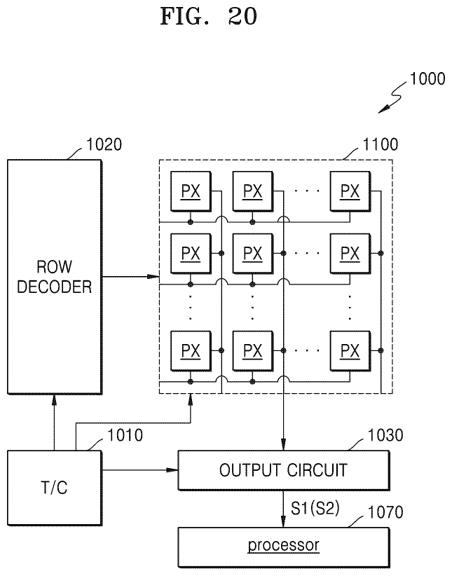

FIG. 19 is a cross-sectional view showing a schematic structure of an image sensor according to an embodiment, and FIG. 20 is a block diagram showing a circuit configuration of the image sensor of FIG. 19. Referring to FIGS. 19 and 20, an image sensor 1000 may include a pixel array 1100 including a plurality of pixels PX. The pixel array 1100 may include a plurality of pairs of photosensing elements SE and photosensing elements SE. Each pair of the photosensing element SE and the photosensing element SE may be referred to as a pixel PX. The photosensing elements SE may constitute a sensor array 1110, and the filter elements FE may constitute a filter array 1130. Each of the photosensing elements SE of the sensor array 1110 may adopt the photodetector 100 described above. A separation layer may be formed between neighboring ones of the photosensing elements SE. The filter elements FE may be positioned on the photosensing elements SE, respectively. The filter elements FE may be band pass filters for a preset wavelength band, and filter elements FE of proper wavelength bands may be set according to kinds of images that the image sensor 100 intends to obtain. The filter elements FE may be, for example, band pass filters for a visible light band or band pass filters for an infrared band. The filter array 130 may include a plurality of kinds of filter elements that pass a plurality of different wavelength bands. The filter array 1130 may be a color filter.

The image sensor 1000 may include a circuitry for reading a photoelectric signal generated from each of the plurality of photosensing elements SE, the circuitry including a plurality of circuit elements respectively connected to the plurality of photosensing elements SE. At least a portion of the circuitry may be included in a circuit board SU shown in FIG. 19, and the photosensing elements SE may be positioned on the circuit board SU to be connected to the circuit elements in the circuit board SU. The image sensor 1000 may include the pixel array 1100, a timing controller 1010, a row decoder 1020, an output circuit 1030, and a processor 1070. The timing controller 1010, the row decoder 1020, the output circuit 1030, and the processor 1070 may be implemented as a single chip or a plurality of separate chips.

The pixels PX of the pixel array 1100 may be arranged two-dimensionally along a plurality of rows and columns. The row decoder 1020 may select one from among the rows of the pixel array 1100 in response to a row address signal output from the timing controller 1010. The output circuit 1030 may output a photosensing signal in unit of a column from a plurality of pixels arranged along the selected row. To this end, the output circuit 1030 may include a column decoder and an analog to digital converter (ADC). For example, the output circuit 1030 may include a plurality of ADCs each arranged for each column between the column decoder and the pixel array 1100, or an ADC positioned at an output terminal of the column decoder.

The processor 1070 may form an image by processing an electrical signal from the output signal 1030. Because the pixels PX provided in the image sensor 1000 according to the embodiment use, as the photosensing element SE, the photodetector 100 capable of detecting light in the visible light band and the infrared band, an electric signal output from the output circuit 1030 may include a photoelectric signal S1 by visible light and/or a photoelectric signal S2 by infrared light. Accordingly, the processor 1070 may process these signals to form a visible light image and/or an infrared image or to form a three-dimensional image. For example, the processor 1070 may form a two-dimensional image from the photoelectric signal S1 by visible light, calculate depth information of each location of the two-dimensional image from the photoelectric signal S2 by infrared light by using a time of flight (ToF) method, and then combine the depth information with the two-dimensional image, thereby forming a three-dimensional image. Because the photodetector 100 detects light of an infrared band, the processor 1070 may form an infrared image.

According to the above-described embodiments of the photodetector, the Schottky junction structure using Ge may enable the detection of light in the NIR and SWIR bands. Also, integrating the tunneling barrier layer to increase the thickness of the Schottky barrier, may reduce or prevent dark current arising from quantum mechanical tunneling by majority carriers having low energy.

According to the above-described embodiments of the photodetector, the photodetector may be driven at a lower voltage than an existing P-N junction structure, may achieve fast switching, and may be manufactured by a simpler manufacturing process than that of the existing P-N junction structure to thereby reduce mass production cost.

The above-described embodiments of the photodetector may be applied to image sensors capable of responding to various wavelength bands.

Although the photodetector and the image sensor including the same have been described with reference to the embodiments shown in the drawings, the embodiments are only examples, and it will be understood by those of ordinary skill in the art that various modifications or other equivalent embodiments may be made from the embodiments. The scope of the disclosure is defined in the accompanying claims rather than the above detailed description, and it should be noted that all differences falling within the claims and equivalents thereof are included in the scope of the disclosure.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A photodetector comprising:
a first semiconductor layer comprising germanium (Ge);
a conductive layer that, in conjunction with the first semiconductor layer, forms a Schottky junction structure; and
a tunneling barrier layer positioned between the first semiconductor layer and the conductive layer and configured to prevent or reduce dark current between the first semiconductor layer and the conductive layer.

2. The photodetector of claim 1, wherein
the first semiconductor layer comprises intrinsic-Ge, epitaxially grown Ge, or GeₓSn₁₋ₓ, and x satisfies 0<x<1.

3. The photodetector of claim 1, further comprising
a semiconductor substrate,
wherein the first semiconductor layer is formed on the semiconductor substrate.

4. The photodetector of claim 1, further comprising:
a semiconductor substrate doped with one of a p type and an n type; and
a second semiconductor layer formed on the semiconductor substrate and doped with another one of the p type and the n type,
wherein the first semiconductor layer is formed on the second semiconductor layer, and
wherein the first semiconductor layer is doped with one of a p-type and an n-type.

5. The photodetector of claim 1, further comprising:
a semiconductor substrate doped with one of a p type and an n type; and
a doping region formed in the semiconductor substrate and doped with another one of the p type and the n type,
wherein the first semiconductor layer is formed on the doping region.

6. The photodetector of claim 1, wherein
the conductive layer comprises a first conductive layer that, in conjunction with the first semiconductor layer, forms the Schottky junction structure.

7. The photodetector of claim 6, further comprising
a second conductive layer positioned on the first conductive layer and being transparent.

8. The photodetector of claim 7, wherein
the first conductive layer comprises a metal, an alloy, a metal oxide, a metal nitride, or a silicide, and
the second conductive layer comprises indium tin oxide (ITO), indium tungsten oxide (IWO), indium zinc oxide (IZO), gallium doped zinc oxide (GZO), gallium indium zinc oxide (GIZO), or aluminum zinc oxide (AZO).

9. The photodetector of claim 7,
wherein a work function of the first conductive layer is set such that a Schottky barrier height of the Schottky junction structure has a lower value than that of a junction structure of the second conductive layer and the semiconductor layer.

10. The photodetector of claim 1,
wherein the tunneling barrier layer increases a thickness of a Schottky barrier formed between the conductive layer and the first semiconductor layer.

11. The photodetector of claim 1,
a difference between a conduction band energy level of the tunneling barrier layer and electron affinity of the first semiconductor layer is 0.5 eV or less.

12. The photodetector of claim 1,
wherein bandgap energy of the tunneling barrier layer is greater than bandgap energy of the first semiconductor layer.

13. The photodetector of claim 1,
wherein bandgap energy of the tunneling barrier layer is 2 eV or greater.

14. The photodetector of claim 1, wherein
a thickness of the tunneling barrier layer is 30 nm or less.

15. The photodetector of claim 1,
wherein the tunneling barrier layer comprises a metal oxide.

16. The photodetector of claim 15, wherein
the metal oxide comprises titanium dioxide (TiO₂), tin dioxide (SnO₂), zinc oxide (ZnO), tungsten trioxide (WO₃), niobium pentoxide (Nb₂O₅), barium tin trioxide (BaSnO₃), dizinc tin tetroxide (Zn₂SnO₄), strontium titanium trioxide (SrTiO₃), barium titanium trioxide (BaTiO₃), zinc tritanate (Zn₂Ti₃O₈), silica (SiO₂), alumina (Al₂O₃), hafnia (HfO₂), magnesium oxide (MgO), molybdenum trioxide (MoO₃), diiron trioxide (Fe₂O₃), tantalum pentoxide (Ta₂O₅), tantalum oxynitride (TaON), or diindium trioxide (In₂O₃).

17. The photodetector of claim 15, wherein
the metal oxide comprises titanium oxide TiO₂, TiO₂-x, TiO, Ti₂O, Ti₃O, Ti₂O₃, or TiₙO₂ₙ₋₁, wherein x satisfies 0<x<1, and n is an integer ranging from 3 to 9.

18. The photodetector of claim 1, wherein
the tunneling barrier layer comprises a metal oxide and silicon oxide.

19. An image sensor comprising:
a sensor array comprising a plurality of photo-sensing elements, wherein the plurality of photo-sensing elements comprises a plurality of photodetectors, respectively; and
at least one processor configured to read photoelectric signals generated from the plurality of photo-sensing elements,
wherein at least one of the plurality of photodetectors comprises:
a first semiconductor layer comprising germanium;
a conductive layer that, in conjunction with the first semiconductor layer, forms a Schottky junction structure; and
a tunneling barrier layer positioned between the first semiconductor layer and the conductive layer and configured to prevent or reduce dark current between the first semiconductor layer and the conductive layer.
